(19) United States
(12) Patent Application Publication
(10) Pub. No.: US 2011/0272003 A1
(43) Pub. Date: Nov. 10, 2011

(54) COMBINED SOLAR THERMAL POWER GENERATION AND A POWER STATION THEREFOR

(75) Inventor: Ami Elazari, Tel-Aviv (IL)

(73) Assignee: T. O. U. MILLENNIUM ELECTRIC LTD.

(21) Appl. No.: 12/450,206

(22) PCT Filed: Mar. 16, 2008
(86) PCT No.: PCT/IL2008/000368

§ 371 Date: Aug. 1, 2011

Related U.S. Application Data
(60) Provisional application No. 60/907,007, filed on Mar. 16, 2007.

(51) Int. Cl. H01L 31/058; F01K 13/00; F01K 7/38

(52) U.S. Cl. 136/248; 60/670; 60/645

(57) ABSTRACT

A power generation apparatus comprising: a photovoltaic power generation unit; a coolant system for the photovoltaic power generation unit, configured to provide coolant over the photovoltaic power generation unit and to extract coolant after use; and a turbine power generation unit, configured for operation by fluid at least partly heated by a first heat exchanger using said extracted coolant.

### FIELD AND BACKGROUND OF THE INVENTION

The present invention, in some embodiments thereof, relates to a combined solar thermal power generation system and operating method and a power station therefor.

Combined solar thermal power stations are relatively new. Operational examples are few but include the following:
Solar Energy Generating Systems, USA Mojave desert California, with an installed total of 354 MW, uses a parabolic trough design.
Nevada Solar One, USA Nevada, 64 MW, installed capacity, also uses a parabolic trough design
Liddell Power Station, Australia, 95 MW heat, installed capacity is 35 MW electrical equivalent as steam input for conventional power station, uses a Fresnel reflector design
PS10 solar power tower, Spain Seville, much smaller installed capacity at 11 MW, a power tower design.

The above systems use solar heating to heat water or oil and then in various ways uses the heat to power turbines, from which the electricity generation occurs. Thus solar power becomes the power source for generator operation.

A number of technologies are available. As well as the parabolic trough, power tower, and Fresnell reflector referred to above there is the solar dish/stirling engine. A single solar dish-Stirling engine installed at Sandia National Laboratories National Solar Thermal Test Facility produces as much as 25 kW of electricity, with a conversion efficiency of 40.7%.

Solar parabolic trough plants have been built with efficiencies of about 20%. Fresnel reflectors have an efficiency that is slightly lower (but this is compensated by the denser packing).

The gross conversion efficiencies (taking into account that the solar dishes or troughs occupy only a fraction of the total area of the power plant) are determined by net generating capacity over the solar energy that falls on the total area of the solar plant. The 500-megawatt (MW) SCE/SES plant would extract about 2.75% of the radiation (1 kW/m²) that falls on its 4,500 acres (18.2 km²). For the 50 MW AndaSol Power Plant that is being built in Spain (total area of 1,300×1,500 m=1.95 km²) gross conversion efficiency comes out at 2.6%.

Another form of solar energy generation is the photovoltaic cell. There are a number of ways of manufacturing the cell and all have various advantages and disadvantages. The photovoltaic cell generates electricity directly.

Thus the skilled person wishing to install electrical power generation today must choose between solar thermal power generation and photovoltaic cells.

### SUMMARY OF THE INVENTION

The present invention in some embodiments provides combined photovoltaic and solar thermal power generation in an integrated fashion as a combined cycle. Coolant is used to keep the photovoltaic cells at their designed temperature and then is itself used in operation of the turbines.

According to an aspect of some embodiments of the present invention there is provided a power generation apparatus comprising:

a photovoltaic power generation unit;

a coolant system for the photovoltaic power generation unit, configured to provide coolant over the photovoltaic power generation unit and to extract coolant after use; and

a turbine power generation unit, configured for operation by fluid at least partly heated by a first heat exchanger using the extracted coolant.

In an embodiment, the photovoltaic power generation unit comprises a plurality of photovoltaic modules with integral heat exchange features.

An embodiment may comprise a second heat exchange unit located between the photovoltaic power generation unit and the turbine power generation unit to obtain heated fluid from a thermal solar unit to boost a temperature of the turbine fluid after heating via the first heat exchanger and before application to the turbine power generation unit.

In an embodiment, the turbine comprises a two-stream double entry steam turbine, and wherein there is provided a first path for the turbine fluid through the first heat exchange unit, thereby to provide the first stream and wherein there is provided a second path for the turbine fluid through the first heat exchange unit and the second heat exchange unit, thereby to provide the second stream.

In an embodiment, the first stream of the first path comprises a relatively large volume of steam at a lower pressure, and the second stream of the second path comprises a smaller volume of steam at a relatively higher pressure.

An embodiment may be configured to provide a power station.

According to a second aspect of the present invention there is provided a power generation method comprising:

generating electricity using photovoltaic power generation modules;

providing coolant over the photovoltaic power generation modules to maintain the modules at a predetermined temperature;

extracting the coolant after use; and

using the coolant to heat a turbine operating fluid to operate a turbine, therewith to generate additional electricity.

An embodiment may comprise combining photovoltaic power generation modules with integral heat exchange features.

An embodiment may comprise obtaining additional heated fluid from a thermal solar unit to further boost a temperature of the turbine fluid after heating via the coolant and before application to the turbine power generation unit.

In an embodiment, the turbine comprises a two-stream double entry steam turbine, and wherein there is provided a first path for the turbine fluid via the coolant, thereby to provide the first stream and wherein there is provided a second path for the turbine fluid via the coolant and the additional heated fluid, thereby to provide the second stream.

In an embodiment, the first stream of the first path comprises a relatively large volume of steam at a lower pressure, and the second stream of the second path comprises a smaller volume of steam at a relatively higher pressure.

Unless otherwise defined, all technical and/or scientific terms used herein have the same meaning as commonly understood by one of ordinary skill in the art to which the invention pertains. Although methods and materials similar or equivalent to those described herein can be used in the practice or testing of embodiments of the invention, exemplary methods and/or materials are described below. In case of conflict, the patent specification, including definitions, will control. In addition, the materials, methods, and examples are illustrative only and are not intended to be necessarily limiting.

### BRIEF DESCRIPTION OF THE DRAWINGS

Some embodiments of the invention are herein described, by way of example only, with reference to the accompanying drawings. With specific reference now to the drawings in detail, it is stressed that the particulars shown are by way of example and for purposes of illustrative discussion of embodiments of the invention. In this regard, the description taken with the drawings makes apparent to those skilled in the art how embodiments of the invention may be practiced.

In the drawings:

FIG. 1 is a simplified schematic diagram showing a first embodiment of the present invention;

FIG. 2 is a simplified schematic diagram showing a cooled solar panel for use with the embodiment of FIG. 1;

FIG. 3 is a simplified schematic diagram showing a power generation scheme according to a second embodiment of the present invention;

FIG. 4 is a simplified schematic diagram showing a layout for a power station based on an embodiment of the present invention;

FIG. 5 is a simplified schematic diagram showing a layout for a power station based on an alternative embodiment of the present invention;

FIG. 6 is a graph showing a temperature cycle used in a preferred embodiment of the present invention; and

FIG. 7 is the Mollier chart.

### DESCRIPTION OF EMBODIMENTS OF THE INVENTION

The present invention, in some embodiments thereof, relates to a combined solar thermal and photovoltaic power generation system and method and a power station therefor.

Before explaining at least one embodiment of the invention in detail, it is to be understood that the invention is not necessarily limited in its application to the details of construction and the arrangement of the components and/or methods set forth in the following description and/or illustrated in the drawings and/or the Examples. The invention is capable of other embodiments or of being practiced or carried out in various ways.

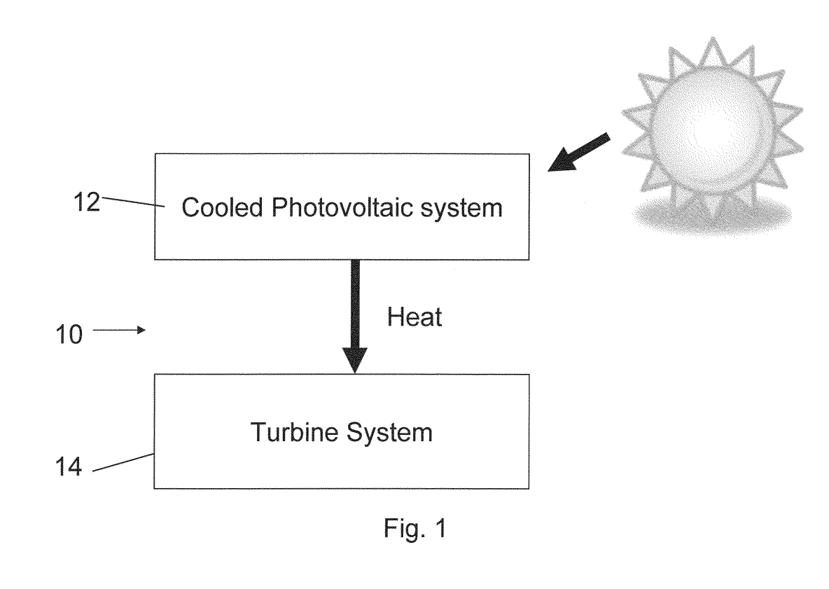

Referring now to the drawings, FIG. 1 is a simplified schematic diagram showing power generation apparatus 10 according to a first embodiment of the present invention. The apparatus includes a photovoltaic power generation unit 12, which is typically an array of solar panels, each panel including an array of photovoltaic modules. The photovoltaic modules may be constructed using any of several available technologies, each technology having its advantages and disadvantages. The photovoltaic modules 12 are cooled, as will be explained below, since the modules have temperature efficiency curves and work at maximum efficiency if kept substantially at the maximum of the curve. Solar radiation generally tends to heat the cells above their point of peak efficiency so cooling increases their efficiency.

The coolant is extracted from the photovoltaic system after use, that is when it has been heated. Heat from the extracted coolant is then passed to the fluid circuit of turbine system 14, so that the turbine fluid is heated, effectively for free.

The turbine system 14 includes a turbine power generation unit, typically a steam turbine, which is operated by a stream of steam and generates electricity by electromagnetic induction in the conventional manner. There is thus provided an overall system wherein there are two overall sources of electricity, photovoltaic cells and the turbine, and further, coolant from the photovoltaic cells is used to heat water for the turbine, thus providing a combined cycle.

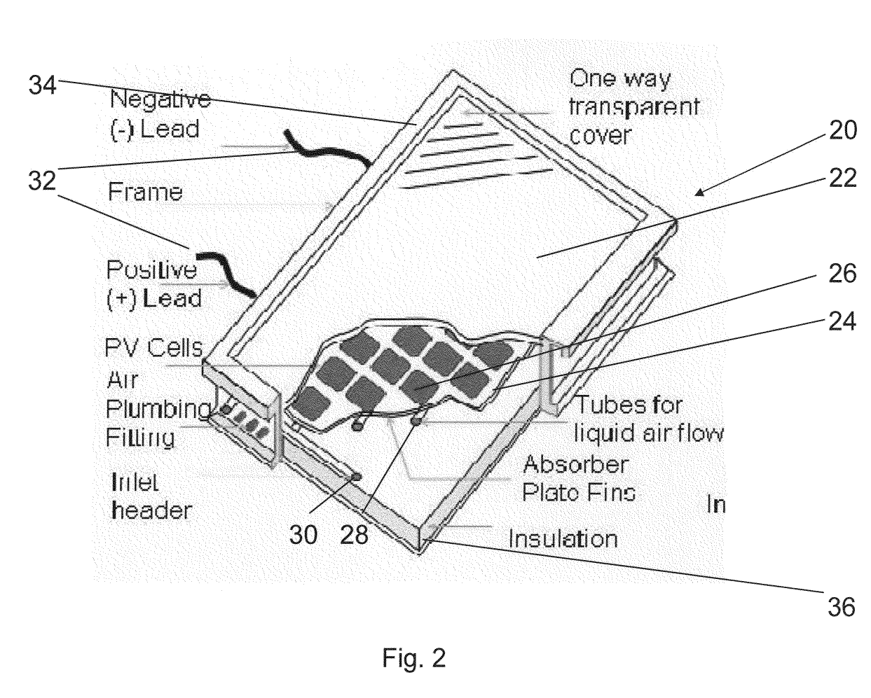

Reference is now made to FIG. 2 which is a simplified diagram illustrating a solar panel 20 for use in the cooled photovoltaic system of FIG. 1. The solar panel includes integral heat exchange features. The panel 20 comprises a one-way transparent cover 22 over a layer 24 of photovoltaic cells 26. In thermal contact with the layer 24 are heat exchange fins and fluid pipes 28. The fluid may be water, oil or air or any other suitable fluid. An inlet header 30 is also preferably provided as are electrical connections 32. The whole is located within frame 34 and underlaid by insulator 36.

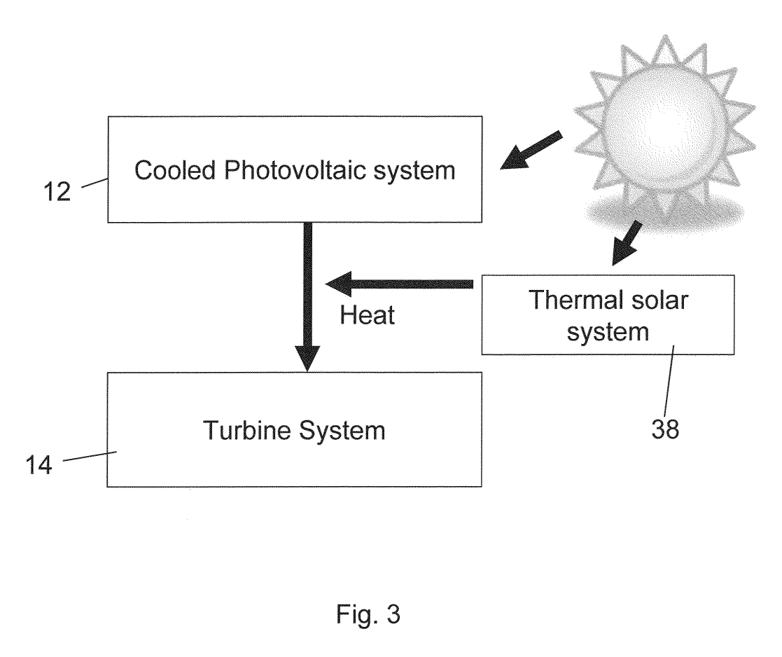

Reference is now made to FIG. 3, which shows a second embodiment of the present invention. As will be explained in greater detail below, the coolant from the photovoltaic system may not provide sufficient heat for the turbine system. Thus a thermal solar system 38 may be provided, using any of the available thermal solar technologies as may be selected by the skilled person, to heat fluid using solar energy to temperatures that are higher than those available from the coolants of system 12. A system of heat exchange is then used to apply the heat gained in the solar thermal system to the turbine fluid, typically via a second heat exchange unit, as will be described in greater detail below. This second heat exchange unit may be located between the photovoltaic power generation unit 12 and the turbine power generation unit 14 so that this second round of heat is applied to an already heated fluid following contact with the thermal solar unit. The result is to boost the temperature of the turbine fluid even further after heating via the first heat exchanger and before application to the turbine power generation unit.

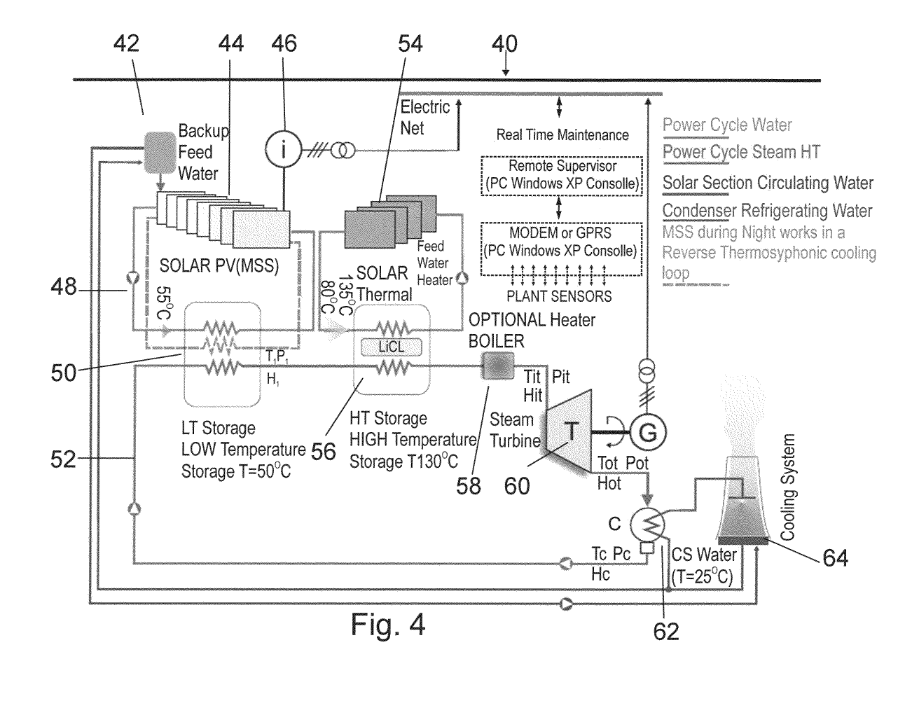

Reference is now made to FIG. 4, which is a simplified schematic diagram of a power plant 40 based on combined photovoltaic and thermal solar energy. Feed water for the system is available at backup feed water reservoir 42. Photovoltaic cells in arrays and panels are provided at 44 and generate current i 46. Solar panel coolant circulates via circuit 48 to heat exchanger 50 where it exchanges heat with the turbine steam circuit 52, thus heating the turbine circuit with heat energy h₁ to reach temperature T₁ at pressure P₁, and cooling the solar panels.

Solar thermal installation 54 provides additional heating of fluid which is used in high temperature heat exchanger 56 to heat the turbine circuit even further, this time with heat energy h_{iT} to reach temperature T_{iT} at pressure P_{iT}. An optional boiler 58 may be provided for use when the solar energy is not sufficient. Typically after the second heat exchange 56, the turbine fluid has reached a steam state. In the steam state the turbine fluid enters the turbine 60 and current G is generated. The steam is cooled via condenser 62 and cooling tower 64, back to energy h₀ at temperature T₀ and pressure P₀, ready for another cycle.

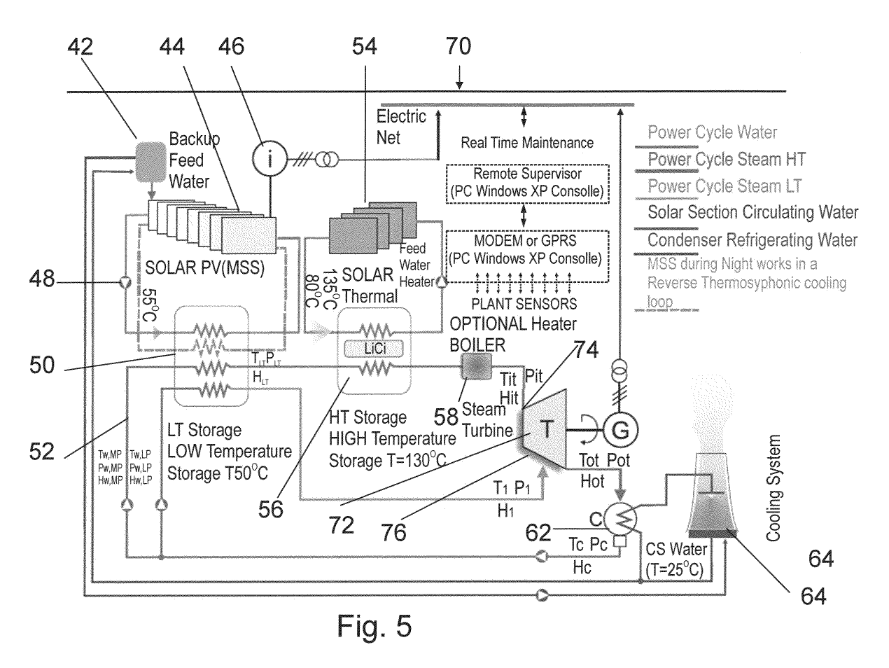

Reference is now made to FIG. 5, which is a variation on the apparatus of FIG. 4. Parts that are the same as in FIG. 4 are given the same reference numerals and are not described again except as necessary for an understanding of the present embodiment.

The turbine 72 of FIG. 5 is a double stream double entry steam turbine having a first high pressure high temperature steam entry 74 and a second low temperature low pressure steam entry 76. The path 52 for the turbine fluid is split into two branches or paths, a first path 78 which passes only through the first heat exchange to provide a large volume of low pressure low temperature steam and a second path 80 which passes through both the first heat exchange unit and the second heat exchange unit to provide a lower volume but higher temperature and higher pressure steam stream.

Referring again to FIG. 1, the present embodiments provide a combined Solar photovoltaic and thermal collector system and a thermal (steam turbine) generator, using the heat thermal energy produced by the two solar systems to add, using the turbine, to the amount of electricity generated by the photovoltaic system alone.

A suitably designed system of cooled photovoltaic cells may itself provide up to 85% generational efficiency made up of 15% electricity, 35% hot water, 35% hot air or total 70% thermal energy. Each Square meter of installed capacity may produce 150 W DC electricity from the PV panels, with 30% higher than conventional efficiency due to the cooling system of the PV, and a total of 700 W thermal energy. This mass of thermal energy is then itself transferred into electrical energy with 25% efficiency by using the thermal turbine based on a low pressure steam generator, as explained in the embodiment of FIG. 4 above.

The panel of FIG. 2, a multi solar (MSS) PV/T/A panel is the basic element of the Solar Photovoltaic/Thermal Power Station. The MSS is a version of the device covered in U.S. Pat. No. 5,522,944, the contents of which are hereby incorporated by reference. The integral cooling system makes it possible to convert solar energy into thermal energy and electric energy at the same time using a single integrated collector.

The thermal steam generator (turbine) is the complementary unit to the MSS collector. The generator makes use of the thermal energy produced by the MSS collector in order to provide an additional and equal amount of energy as is produced by the photovoltaic system.

A solar power station according to the present embodiments may comprise steam generation at 150° C. and a thermal turbine. Existing commercial steam turbines can reach 25% optimal efficiency by using solar thermal energy typically available directly from the cooling system. Such a decrease of the feeding temperature for the steam turbine however leads to dramatic improvement of the economic feasibility, as a result of the smaller solar array required to provide the same output.

A solar thermal/photovoltaic power station may be based on the Multi Solar System panels provided together with solar thermal collector arrays arranged in rows, in order to achieve maximum optimization of the combined system.

It is noted that the solar thermal technology is limited to an operational temperature of 150° C. In consequence the presently preferred embodiments limit the solar steam temperature to a maximum of 130° C., which is the feeding temperature of the thermal turbine. Other commercial steam generators working at higher temperatures, may be more efficient, but are also more expensive to operate. The present embodiments may increase the heat of the steam produced by the solar station, while reaching the optimal temperature for the thermal turbine.

In a trial the temperature output using first level MSS collectors was 55° C.-47° C. The temperature output at the second level, first heat exchange, was 60° C.-100° C. The temperature output at the third] level was 100° C.-150° C. That is to say the system consumes solar thermal energy produced by the MSS collectors at 55° C. at a first level. This temperature is increased by the solar thermal collectors, which are connected in two rows and transferred to the thermal turbine to produce temperatures of up to 150° C. (steam). The thermal turbine produces electricity based on the thermal energy and at 20-25% efficiency. In order to increase efficiency percentages, the option to use tracking devices for the MSS collectors may be considered.

In cases when the heat produced by the Multi Solar System is insufficient to produce steam for the operation of the thermal turbine (especially at winter days), a substitute boiler operated by fuel may provide sufficient energy for the operation of the thermal turbine.

Using the Multi Solar power station with thermal turbine at 150° C. may significantly improve the economic viability of the station, using small amounts of fuel (if any) for the operation of the Multi Solar station. Cooling the water for the Photovoltaic cells may increase the electrical efficiency of the cells by an annual average of 30%. Using the hot water produced by the MSS collector at 55° C. to heat the turbine fluid may save the preheating energy needed to reach this stage. The use of a low temperature (150° C.) low pressure thermal steam turbine may save water and expensive desalination processes.

As explained, the plant is designed to combine photovoltaic (PV) and thermo-solar (TS) electric generation. In particular, the starting point is the use of cooled photovoltaic modules. Cooling enhances the photovoltaic module efficiency, and the cooling fluid can be exploited in a Rankine cycle, producing further power. However, the cooling water temperature at the exit of the photovoltaic (PV) system is rather low (55° C.). Thus, since the Rankine cycle efficiency is strongly dependent on the temperature level, a set of thermal solar modules is added, in order to raise the maximum cycle temperature. Using relatively low cost flat thermal modules, we can attain 135° C. as maximum cycle temperature. Thermal storage may be required in order to stabilize the thermal cycle temperatures.

Referring again to FIG. 4, the two sets of solar panels, PV 44 and TS 54. The condensated operating fluid of the thermal power plant exits the condenser 62 at a temperature Tc slightly higher than ambient temperature, and at the corresponding vapor-liquid equilibrium pressure pc. Extraction and feeding pumps increase its pressure up to the turbine inlet pressure Pᵢₜ. The PV cooling water releases its exceeding heat to the low temperature storage LT. The Rankine compressed liquid is thus heated at T1 by the same LT storage. A second, high temperature, heat storage HT is heated by the water from the thermal solar panels, and provide the heat flux required to evaporate the cycle operating fluid and heat the superheated vapour up to temperature Tᵢₜ. The resulting vapor is then sent to the steam turbine and the condenser. The steam latent heat is removed by the condenser cooling fluid which, in turn, is cooled either in evaporating tower or (at night) using the solar panels themselves as radiating heat sinks.

To further clarify the power plant operations, let us consider a sample application, designed for a PV peak power of the order of 1 MWe, and additional thermal power from the turbine of the same order of magnitude. The following results will obviously be largely dependent on some assumption on the single component efficiencies and performances, among others, turbine efficiency, thermal storage reliability, allowed temperature jump between operating fluid and storage devices, PV modules performances, and thermal solar modules losses.

All of this assumption should be verified for each single actual plant design, together with the proper economic analysis.

Using water as the Rankine operating fluid, the main design parameters are listed in the following:

Steam Turbine estimated nominal power P_{T}=1 MW

Inlet turbine steam temperature Tᵢₜ=130° C.

Condenser temperature T_{c}=30° C.

LT storage exit temperature T₁=50° C.

Maximum Carnot efficiency ηmax=1−Tᵢₜ/T_{c}=1−(30+273)/(130+273)=0.25

Nominal radiation qᵢ=1 kW/m²

PV modules surface S_{PV}=8,000 m²

Solar Thermal surface S_{TS}=4,000 m²

PV modules efficiency η_{e,PV}=P_{PV/qi}=12%

Incoming peak radiation qᵢ=1 kW/m²

Heat Recovery Efficiency from PV:

q_{r,PV}: heat flux available from PV cooling system

η_{r,PV}=q_{r,PV/qi}=70%

Heat Recovery Efficiency from TS:

q_{r,TS}: heat flux available from thermal solar panels

η_{r,TS}=q_{r,TS/qi}=90%

Rankine Cycle

In order to get the proper steam quality at the turbine exit to allow for efficient heat transfer in the condenser and control stability we choose a turbine inlet pressure of 1.9 bar.

In the following, the operating fluid is water. However organic fluid can be used in order to make the heat exchange process more efficient.

The following assumptions apply to the power plant:

Operating fluid: Water

Inlet turbine steam pressure pᵢₜ=1.9 bar

Turbine adiabatic efficiency η_{T,ad}=85%

Condenser pressure pₒₜ=p_{c}=0.045 bar

At peak operating conditions, we assume qᵢ=1 kW/m², yielding a peak power from the PV system given by:

P_{PV}=η_{e,PV}·qᵢ·S_{PV}=9.56 MWe

and an heat flux from the PV cooling system (available at a maximum temperature of 55° C.) of

Q_{LT}=q_{r,PV}·S_{PV}=(η_{r,PV}·qᵢ)·S_{PV}=5.6 MWt (1)

On the other hand, from the thermal solar modules we have

Q_{HT}=η_{r,TS}·qᵢ·S_{TS}=3.6 MWt (2)

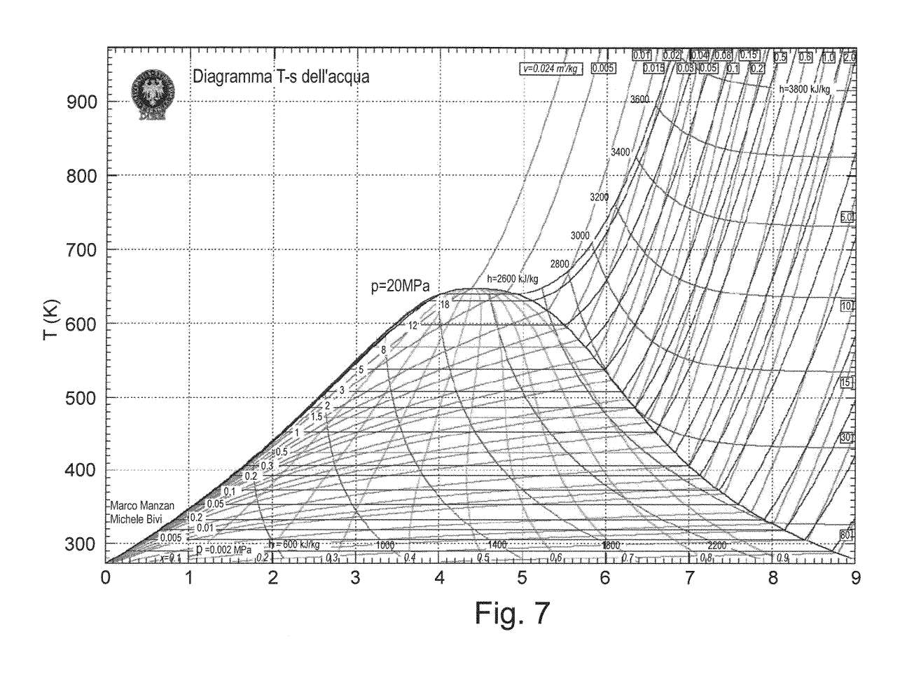

From the Mollier chart (FIG. 7), we can read the turbine inlet and exit enthalpies:

Inlet turbine enthalpy: hᵢₜ=2728 kJ/kg

Outlet turbine enthalpy (assuming turbine efficiency=85%): hₒₜ=2312 kJ/kg

Outlet turbine steam quality: xₒₜ=0.89 kJ/kg

The energy required to heat a kg of condensate from the condenser temperature to the LT storage exit temperature is thus:

Q*₁=c.(T₁−T_{c})=104 kJ/kg

while the heat transfer required to raise the same kg of water from 50° C. to steam at 1.9 bar, 130° C. is

Q*₂=(hᵢₜ−h₁)=2512 kJ/kg

The conclusion from the above is that we need much more heat from the high temperature storage than the lower one. Unfortunately, the ratio between available heat (Eq. 1,2) is just the opposite. This means that if we use a single stream of water/steam in the Rankine cycle we would be able to exploit a only a small portion of the LT heat system, given by

$$\frac{{Q}_{LT , usable}}{{Q}_{LT}} = \frac{{Q}_{HT}}{{Q}_{2}^{*}} \frac{{Q}_{1}^{*}}{{Q}_{LT}} = 3 \%$$

### Two-Stream Steam Turbine

A possible workabout for the above leads to two different steam streams, as per the embodiment of FIG. 5, namely a large, low pressure stream, generating superheated steam at 50° C. (with a low heat to electric power efficiency), and a smaller, medium pressure stream at 130° C.

Both streams may generate power in a single, double entry steam turbine, using a kind of steam turbine known in combined cycle technology.

TABLE 1
Thermal Power Enthalpies

| | Enthalpy | Temperature | Pressure |
|---|---|---|---|
| | [kJ/kg] | [° C.] | [bar] |
| Medium pressure turbine | hᵢₜ = 2728 | Tᵢₜ = 130 | pᵢₜ = 1.9 |
| inlet | | | |
| Medium pressure feedwater | h_{w, MP} ≈ 125.8 | T_{w, MP} ≈ 30 | p_{w, MP} = 1.9 |
| pump exit | | | |
| Low pressure feedwater | h_{w, LP} ≈ 125.8 | T_{w, LP} ≈ 30 | p_{w, LP} = 0.12 |
| pump exit | | | |
| Low pressure turbine inlet | h₁ = 2592 | T₁ = 50 | p₁ = 0.12 |
| Turbine exit | hₒₜ = 2312 | Tₒₜ = 30 | pₒₜ = 0.045 |
| Condenser exit | h_{c} = 125.8 | T_{c} = 30 | p_{c} = 0.045 |
| High pressure stream water | h_{LT} = 209.0 | T_{LT} = 50 | p_{LT} = 0.12 |
| enthapy at LT exit | | | |

From the Rankine charts, we can reconstruct the evolution of both streams, as in Table 1 above showing the thermal power enthalpies. As a final result, if we want to exploit all of the available heat, we will get, at nominal conditions, 0.656 kWe (e=electric) from the high pressure cycle and 0.717 kWe (e=electric) from the lower pressure stream (at a cycle efficiency of 13%).

The Medium Pressure cycle efficiency is given by:

$${η}_{MP} = \frac{{h}_{i τ} - {h}_{ot}}{{h}_{i τ} - {h}_{c}} = 18 \%$$

The Low Pressure cycle has an efficiency of:

$${η}_{LP} = \frac{{h}_{l} - {h}_{ot}}{{h}_{l} - {h}_{c}} = 13 \%$$

The global, weighted average Rankine efficiency is:

$${η}_{Rankine} = \frac{{P}_{MP} + {P}_{LP}}{{Q}_{LT} + {Q}_{HT}} = 15 \%$$

In the end, at nominal conditions we obtain

Photovoltaic power: P_{PV}=0.956 MWe

Turbine power: P_{T}=1.37 MWe.

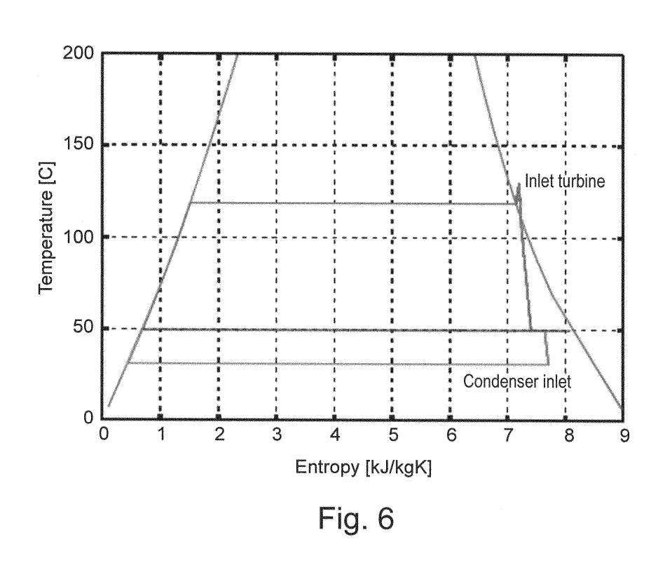

The cycle is shown in FIG. 6.

In terms of energy production throughout the year, we must keep in mind that solar energy is cyclical about the calendar year, and it is not practical to operate the turbine at very low power levels. Typically, depending on latitude, one may expect to operate the turbine for six months, in the hot season. From weather statistics in northern Italy, the average solar energy collected in these six months is 70% of the total. If we assume that ideal storage keeps the operating temperatures constant, then the efficiencies remain constant. Thus, we can compute the yearly energy output under different assumptions. (See Table 4 for the calculations over a range of locations).

For Northern Italy we may obtain from the PV section (assuming a PV efficiency of 12%):

Radiation Ei=1228 kWh/year

EPV=1 173 800 kWh

and from the turbine:

ET=1 180 800 kWh

With a different location, i.e. Southern Italy (again assuming a PV efficiency of 12%):

Radiation Ei=1700 kWh/year

Yielding EPV=1 633 000 kWh

and from the turbine:

ET=1 642 800 kWh

With a different location, i.e. Israel (PV efficiency 15%):

Radiation Ei=1800 kWh/year

PV Efficiency: 15%

Nominal PV power: 1.2 MW

PV energy throughout the year: 2160 MWh/year

Turbine energy throughout the year: 1735 MWh/year

Turbine output with a different Tₘₐₓ, i.e. 150° C.:

Tₘₐₓ=150° C.

T condenser=30° C.

T intermediate=50° C.

PV 8000 m²

Thermal modules 4000 m²

Nominal turbine power=1.42 MW

Energy Yearly Production from Turbine:

In Northern Italy, at 1,227 kWh/year: 1,222 MWh/year

In Israel, at 1,800 kWh/year: 1,798 MWh/year

| | | | | Yearly energy | |
|---|---|---|---|---|---|
| | Plant and environment data | | | output [MWh/y] | |
| | Radiation | PV | T_{it max} | | Tur- |
| Geographical Site | [kWh/y] | efficiency | [° C.] | PV | bine |
| North Italy (UD) | 1,228 | 12% | 130 | 1,173 | 1,180 |
| Center Italy (Roma) | 1,460 | 12% | 130 | 1,399 | 1,407 |
| South Italy (Sicily) | 1,700 | 12% | 130 | 1,633 | 1,642 |
| Israel | 1,800 | 15% | 130 | 2,160 | 1,735 |
| North Italy (UD) | 1,228 | 12% | 150 | 1,173 | 1,222 |
| Israel | 1,800 | 12% | 150 | 2,160 | 1,798 |

The terms “comprises”, “comprising”, “includes”, “including”, “having” and their conjugates mean “including but not limited to”. This term encompasses the terms “consisting of” and “consisting essentially of”.

As used herein, the singular form “a”, “an” and “the” include plural references unless the context clearly dictates otherwise.

It is appreciated that certain features of the invention, which are, for clarity, described in the context of separate embodiments, may also be provided in combination in a single embodiment. Conversely, various features of the invention, which are, for brevity, described in the context of a single embodiment, may also be provided separately or in any suitable subcombination or as suitable in any other described embodiment of the invention. Certain features described in the context of various embodiments are not to be considered essential features of those embodiments, unless the embodiment is inoperative without those elements.

Although the invention has been described in conjunction with specific embodiments thereof, it is evident that many alternatives, modifications and variations will be apparent to those skilled in the art. Accordingly, it is intended to embrace all such alternatives, modifications and variations that fall within the spirit and broad scope of the appended claims.

All publications, patents and patent applications mentioned in this specification are herein incorporated in their entirety by reference into the specification, to the same extent as if each individual publication, patent or patent application was specifically and individually indicated to be incorporated herein by reference. In addition, citation or identification of any reference in this application shall not be construed as an admission that such reference is available as prior art to the present invention. To the extent that section headings are used, they should not be construed as necessarily limiting.

What is claimed is:

1. A power generation apparatus comprising:
a photovoltaic power generation unit;
a coolant system for the photovoltaic power generation unit, configured to provide coolant over the photovoltaic power generation unit and to extract coolant after use; and
a turbine power generation unit, configured for operation by fluid at least partly heated by a first heat exchanger using said extracted coolant.

2. The apparatus of claim 1, wherein said photovoltaic power generation unit comprises a plurality of photovoltaic modules with integral heat exchange features.

3. The apparatus of claim 1, further comprising a second heat exchange unit located between said photovoltaic power generation unit and said turbine power generation unit to obtain heated fluid from a thermal solar unit to boost a temperature of said turbine fluid after heating via said first heat exchanger and before application to said turbine power generation unit.

4. The apparatus of claim 3, wherein said turbine comprises a two-stream double entry steam turbine, and wherein there is provided a first path for said turbine fluid through said first heat exchange unit, thereby to provide said first stream and wherein there is provided a second path for said turbine fluid through said first heat exchange unit and said second heat exchange unit, thereby to provide said second stream.

5. The apparatus of claim 4, wherein said first stream of said first path comprises a relatively large volume of steam at a lower pressure, and said second stream of said second path comprises a smaller volume of steam at a relatively higher pressure.

6. The apparatus of claim 1, configured to provide a power station.

7. A power generation method comprising:
generating electricity using photovoltaic power generation modules;
providing coolant over the photovoltaic power generation modules to maintain said modules at a predetermined temperature;
extracting said coolant after use; and
using said coolant to heat a turbine operating fluid to operate a turbine, therewith to generate additional electricity.

8. The method of claim 7, comprising combining photovoltaic power generation modules with integral heat exchange features.

9. The method of claim 7, further comprising obtaining additional heated fluid from a thermal solar unit to further boost a temperature of said turbine fluid after heating via said coolant and before application to said turbine power generation unit.

10. The method of claim 9, wherein said turbine comprises a two-stream double entry steam turbine, and wherein there is provided a first path for said turbine fluid via said coolant, thereby to provide said first stream and wherein there is provided a second path for said turbine fluid via said coolant and said additional heated fluid, thereby to provide said second stream.

11. The method of claim 10, wherein said first stream of said first path comprises a relatively large volume of steam at a lower pressure, and said second stream of said second path comprises a smaller volume of steam at a relatively higher pressure.
